(19) United States
(12) Patent Application Publication
(10) Pub. No.: US 2009/0309130 A1
(43) Pub. Date: Dec. 17, 2009

(54) METHOD OF FABRICATING COLLECTOR OF IGBT

(75) Inventors: Fu-Yuan Hsieh, HsinChu (TW); CuiXia Wang, HsinChu (TW); Ju Chen, HsinChu (TW); Lin Xu, HsinChu (TW)

Correspondence Address: BAYSHORE PATENT GROUP, LLC, 520 CHANTECLER DR., FREMONT, CA, 94539, US

(73) Assignee: FORCE MOS TECHNOLOGY CO. LTD., HsinChu (TW)

(21) Appl. No.: 12/137,539

(22) Filed: Jun. 12, 2008

(51) Int. Cl. H01L 29/739

(52) U.S. Cl. 257/139; 257/E29.027; 257/E29.197

(57) ABSTRACT

The IGBT is described here that exhibits high breakdown voltage, low on-voltage together with high turn-off speed. The collector of IGBT is formed on the backside of the wafer which has n type float zone. Methods for the p-type collector is implemented by depositing a layer of BSG which is 0.05˜0.1 um on the backside of the wafer and removing it after short time deposition. A thin and high surface concentration p+ layer acts as P type collector of the IGBT is formed on the bottom surface of the wafer. The back metal electrode is sintered to form ohmic contact on the P type collector with high surface concentration. The hole injection efficiency is decreased with a thin layer p+ layer which hat means no P implantation is needed to form the collector and the speed performance of the IGBT is therefore improved.

### FIELD OF THE INVENTION

This invention relates to the general field of power semiconductor device and with particular reference to the fabrication process of IGBT with optimized performance.

### BACKGROUND

It is well-known that IGBT has better characteristics of high blocking-voltage and low on-voltage than the MOSFET in the high voltage field. The thick lightly doped region is used as the voltage sustaining layer and the hole in the p-type collector entering into the voltage sustaining layer reduces the on-state resistance for the resistance modulation effect, which will slow the IGBT switch off at the same time for the recombination of minority and majority carrier. Methods of forming the collector of an IGBT have been studied a lot. One of those methods, using a non-punch through technology, and using ultra-thin float zone wafers is described in a paper 0-7803-3 106-0/96; 1996 I.E.E.E. the p collector is formed by ion implantation on the backside of the lightly n-doped substrate.

In that paper, as shown in FIG. 1, the structure of a non-punch through device with DMOS structure formed in float zone monocrystaline silicon implemented on wafer 50. The float zone 22 of N− dopant is formed in wafer 50. For an N channel device, float zone 22 contains channel diffusions 23 and 24 doped with P type dopant. Within which, source rings 25 and 26 of N+ dopant are implemented. And for a P channel device, these concentrations introduced above will be reversed. Then, a gate oxide 30 will be deposited on top of the channel regions 23 and 24, and followed by forming a conductive polysilicon gate 31. A low temperature oxide 32 is then deposited on top of the polysilicon gate 31 to insulate the gate from the emitter electrode 35. After the DMOS structure is completed, steps of grinding and etching are implemented respectively. Later, a weak collector 60 is formed on the bottom surface 53 and then is the formation of a collector electrode 61.

As described in that paper, the non-punch through IGBT of this structure has optimized performances such as reasonable on-state voltage, high short-circuit ruggedness, and minimal turn-off losses without heavy metal or E-beam lifetime killing. Moreover, the cost is also reduced as compared to fabricating IGBTs with epitaxial layers because IGBTs with this structure are fabricated on low-cost bulk silicon substrates.

However, as wafer breakage is always observed during Ion Implantation, subsequent anneal and metallization as result of thin wafer, there are still some constraints in the use of this shallow P type Implant method.

In the U.S. Pat. No 5,485,022, a collector structure is formed by ion implantation at limited area on backside of the wafer which needs another mask to configure the limited area. Then a metal electrode 9 is sintered into the limited area of the bottom of the wafer. As Turn-off time depends on the amount of the hole entering into the base region of the IGBT, this method described in U.S. Pat. No. 5,485,022 can decrease switch-off time, but brought problems which will result in high contact resistance for the small contact area of the collector with the metal electrode and increased cost for adding a mask to form the limited area of collector.

Accordingly, it would be desirable to provide a novel method of forming optimum p type collector with low cost process.

### SUMMARY OF THE INVENTION

The present invention provides a non-punch through IGBT having a thin P collector layer and a novel method to form it.

In accordance with the invention, the collector of an IGBT is formed by depositing a layer of BSG atop the backside of the wafer after it is thinned to its desired thickness. The layer of BSG is removed after the said wafer is placed in the deposition chamber for a short time, and a back electrode, for example, subsequently deposited layers of aluminum, titanium, nickel-vanadium and silver, is sintered on the bottom surface of wafer as the collector electrode.

The BSG layer is APCVD or PECVD deposited on the backside of the wafer. It takes a little time to form a BSG layer about 0.05˜0.1 um for the deposition rate of BSG is high in the low temperature about 300˜450° C., and the diffusion rate of the boron in the silicon is faster than in the dioxide silicon, so the boron dopant easily diffuses into the silicon to form a shallow P type collector in the deposition step. And no anneal process is needed for the boron concentration is in the range of about 0.6˜1.0 weight percentage in the BSG film. As turn-off performance of the device depends on the collector, shallower the collector junction means to smaller the turn-off time, collector formed by the method of this invention is shallower than 0.1 um, so the device fabricated by present invention shows significant high frequent characteristic.

This process can produce high surface concentration and shallow junction which has two merits as follows: first, high surface concentration junction can form the ohmic contact between the metal electrode, then, shallow junction as collector results in faster switching device. Shallower the P+ collector is, smaller the amount of minority carriers to recombine, so that, the turn-off performance of this device fabricated with this invention is improved greatly.

In addition, the elimination of collector formed by implantation avoids possible breakage of wafers in the manufacturing process.

It should be pointed out the P type collector is formed after the standard process of DMOS has finished in the top of the thick wafer. Grinding the wafer to the thickness which ranges from about 80 microns to 250 microns depending on the desired voltage rating, thereafter, the thinned wafer is released stress in the low-temperature apparatus. The present invention is then used to form the p type collector through the BSG layer, the collector electrode is formed after removing the BSG.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1 is a cross-section of a small portion of a prior art type of non-punch through IGBT formed in float zone material with an implanted collector.

FIG. 2 is a cross-section of a small portion of a prior art of IGBT with limited area of collector.

FIG. 3 shows steps of forming the device junctions and emitter electrode for both prior art of FIG. 1 and for the present invention.

FIG. 4 shows the deposition of BSG which is 0.05˜0.1 um on the bottom of the wafer of FIG. 3 in accordance with the present invention.

FIG. 5 shows the formation of the bottom electrode on the wafer of FIG. 4 after the BSG is removed.

### DETAILED DESCRIPTION OF THE EMBODIMENTS

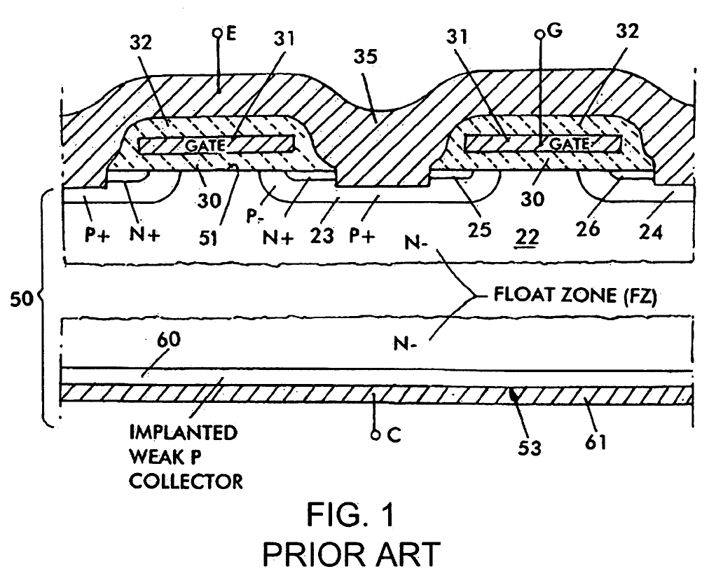

As described above, FIG. 1 shows a small portion of a prior art type of non-punch through IGBT formed in float zone material which has an implanted collector. Note that the implanted collector may lead to cost increase due to frequent wafer breakage during manufacturing process.

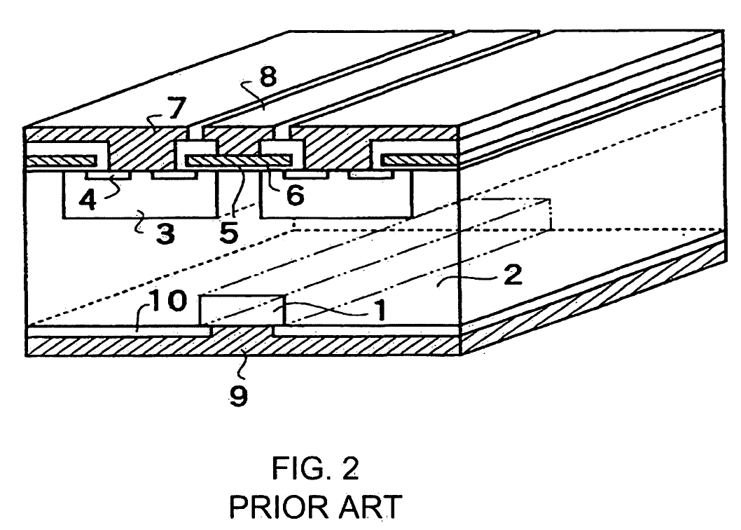

FIG. 2 shows another prior art of IGBT with limited area of collector as mentioned above. Although this kind of structure is capable of performing a low on-voltage and a high turn-off speed, it is a big constraint in the aspect of proving a low contact resistance.

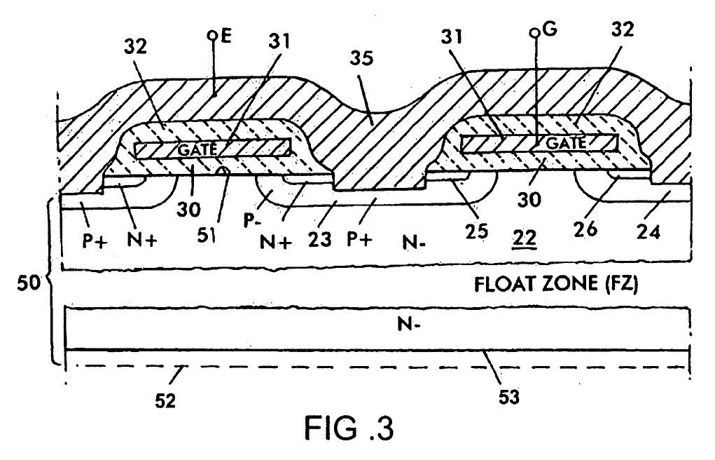

FIG. 3 illustrates initial steps of forming device junction which is about 0.1 um and top electrode for both structure of FIG. 1 and for the present invention. In FIG. 3, after the top DMOS structure is completed, a step of grinding is implemented to make the float zone wafer 50 close to its desired thickness. And then the bottom surface of wafer 50 is etched to surface 53 for stress relief. Furthermore, the concentration of the float zone wafer 50 is about 1E14 per cm³.

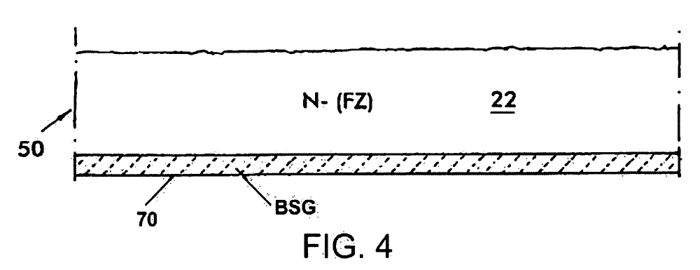

FIG. 4 is a small portion of FIG. 3 to illustrate the deposition of BSG 70 on the bottom surface 50 of wafer 50. The APCVD or PECVD deposition is operated in low temperature of 300˜450° C., so the boron dopant in the BSG will diffuse into the bottom surface 50 to form P+ collector.

The BSG layer has a thickness of 0.05˜0.1 um and a concentration of 1E19˜1E20 per cm³. The thickness and the concentration of this layer are very important to the performance of an IGBT device.

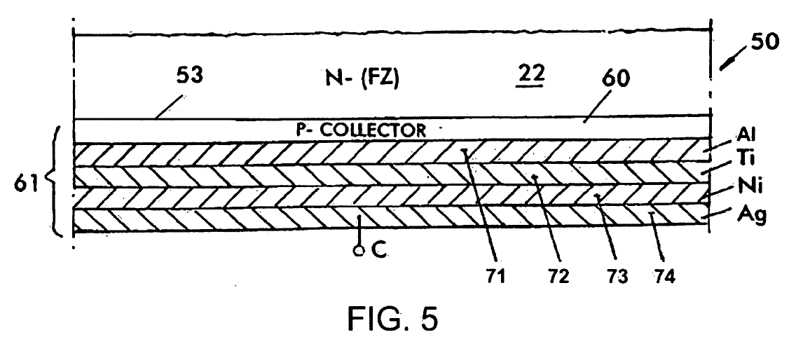

After the BSG layer 70 is removed, a thin and high surface concentration P type collector 60 is formed. As shown in FIG. 5, the back electrode 61 is then formed to be a favorable ohmic contact on the P type collector 60. The back electrode, for example, consists of four different layers of metal, aluminum layer 71, titanium layer 72, nickel vanadium layer 73 and silver layer 74.

Although the present invention has been described in terms of the presently preferred embodiment, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A non-punch through IGBT device implemented in a float zone wafer, with a BSG layer deposited on the back side of said wafer to form the collector, comprising:
a float zone wafer having two parallel surfaces;
a DMOS structure formed in said float zone wafer;
a BSG layer deposited to form the collector and removed later.

2. The IGBT device of claim 1, wherein said float zone wafer has a concentration of 1E14 per cm³.

3. The IGBT device of claim 1, wherein after said DMOS structure is formed, thinning said wafer to its desired thickness, then depositing said BSG layer with boron dopant on the back surface of said wafer.

4. The IGBT device of claim 1, wherein said BSG layer has a thickness of 0.05˜0.1 um and a concentration of 1E19˜1E20 per cm.

5. The IGBT device of claim 1, wherein said BSG layer forms a P+ junction having a depth less than 0.1 um.

6. The BSG layer of claim 3, wherein no anneal process is needed to active the junction for the formation of P+ area after said BSG layer is deposited.

7. The BSG layer of claim 3, wherein said BSG layer will be removed after said deposition.
